(19) United States
(12) Patent Application Publication
(10) Pub. No.: US 2017/0170309 A1
(43) Pub. Date: Jun. 15, 2017

(54) THIN FILM TRANSISTOR, ARRAY SUBSTRATE AND DISPLAY DEVICE HAVING THE SAME, AND METHOD THEREOF

(71) Applicant: BOE TECHNOLOGY GROUP CO., LTD., Beijing (CN)

(72) Inventor: Xiang Liu, Beijing (CN)

(73) Assignee: BOE TECHNOLOGY GROUP CO., LTD., Beijing (CN)

(21) Appl. No.: 15/037,880

(22) PCT Filed: Dec. 10, 2015
(86) PCT No.: PCT/CN2015/096941

§ 371 Date: May 19, 2016

(30) Foreign Application Priority Data
Jun. 25, 2015 (CN) 201510358954.4

(51) Int. Cl. H01L 29/786; H01L 21/34; H01L 21/02

(52) U.S. Cl. CPC H01L 29/786; H01L 21/02581; H01L 21/02554; H01L 21/02565; H01L 21/34

(57) ABSTRACT

The present application discloses a thin film transistor comprising a source electrode; a drain electrode; an active layer; a first connecting layer connecting the active layer to the source electrode; a second connecting layer connecting the active layer to the drain electrode; and an insulating layer between the first connecting layer and the second connecting layer.

### CROSS-REFERENCE TO RELATED APPLICATION

This application claims priority to Chinese Patent Application No. 201510358954.4, filed Jun. 25, 2015, the contents of which are incorporated by reference in the entirety.

### FIELD

The present invention relates to display technology, more particularly, to a thin film transistor, an array substrate and a display device having the same, and a method of manufacturing thereof.

### BACKGROUND

Display devices such as liquid crystal display (LCD) and organic light-emitting diode (OLED) have been widely used. LCD and OLED display devices use thin film transistor (TFT) to control pixels in the display panel. Examples of TFT include amorphous silicon TFT, polycrystalline silicone TFT, single crystal silicon TFT, and metal oxide TFT.

### SUMMARY

In one aspect, the present invention provides a thin film transistor comprising a source electrode; a drain electrode; an active layer; a first connecting layer connecting the active layer to the source electrode; a second connecting layer connecting the active layer to the drain electrode; and an insulating layer between the first connecting layer and the second connecting layer. The insulating layer, the first connecting layer, and the second connecting layer are integrally formed and disposed on the active layer, the first connecting layer and the second connecting layer are conductive.

Optionally, the first connecting layer and the second connecting layer comprise n+ amorphous silicon, and the insulating layer comprises SiOₓ or SiNₓ.

Optionally, the active layer comprises an oxide material.

Optionally, the oxide material is selected from the group consisting of the following or combination of: HfInZnO (HIZO), amorphous InGaZnO (amorphous IGZO), InZnO, amorphous InZnO, ZnO:F, In₂O₃:Sn, In₂O₃:Mo, Cd₂SnO₄, ZnO:Al, TiO₂:Nb, and Cd—Sn—O.

Optionally, the thin film transistor is a bottom gate thin film transistor further comprising a gate electrode disposed below the active layer; and a gate insulating layer between the gate electrode and the active layer.

Optionally, the thin film transistor is a top gate thin film transistor further comprising a gate insulating layer disposed on top of the source electrode and the drain electrode; and a gate electrode on top of the gate insulating layer.

In another aspect, the present invention provides a method of manufacturing a thin film transistor. The method comprises forming a pattern comprising an active layer and a conversion layer disposed on the active layer in a single patterning process, wherein the conversion layer and the active layer have a same pattern, and the conversion layer is made of a conductive material; and treating a region of the conversion layer and converting the conductive material within the region into an insulating material, thereby forming an insulating layer.

Optionally, the treating is performed by an oxidation process or a nitrification process.

Optionally, the method further comprises forming a pattern comprising a source electrode layer; and forming a pattern comprising a drain electrode layer.

Optionally, the conversion layer comprises a first region contacting the source electrode; a second region contacting the drain electrode; and a third region between the first region and the second region.

Optionally, the method further comprises treating the third region and converting the conductive material within the third region into the insulating material, thereby forming the insulating layer; wherein the first region and the second region remain conductive, thereby forming a first connecting layer connecting the active layer to the source electrode and a second connecting layer connecting the active layer to the source electrode.

Optionally, the step of forming the pattern comprising the active layer and the conversion layer comprises sequentially depositing a first material for forming the active layer and a second material for forming the conversion layer; wherein the second material comprises n+ amorphous silicon; and treating the third region and converting the n+ amorphous silicon within the third region into SiOₓ by the oxidation process or SiNₓ by the nitrification process.

Optionally, the step of forming the pattern comprising the active layer and the conversion layer comprises sequentially depositing a first material for forming the active layer and a second material for forming the conversion layer; wherein the second material comprises amorphous silicon; n+ doping the second material; and treating the third region and converting the n+ amorphous silicon within the third region into SiOₓ by the oxidation process or SiNₓ by the nitrification process.

Optionally, the oxidation process comprises the following processing parameters: a radio frequency ranging from 3 kW to 15 kW, a pressure ranging from 100 mT to 2000 mT, a gas flow ranging from 1000 sccm to 15000 sccm, and a medium gas comprising O₂ or N₂O.

Optionally, the nitrification process comprises the following processing parameters: a radio frequency ranging from 3 kW to 15 kW, a pressure ranging from 100 mT to 2000 mT, a gas flow ranging from 1000 sccm to 15000 sccm, and a medium gas comprising N₂, NH₃, or a mixture of N₂ and NH₃.

Optionally, the method further comprises, prior to the step of treating the third region, annealing the conversion layer in a temperature ranging from 300° C. to 600° C.

Optionally, the active layer comprises an oxide material.

Optionally, the oxide material is selected from the group consisting of the following or combination of: HfInZnO (HIZO), amorphous InGaZnO (amorphous IGZO), InZnO, amorphous InZnO, ZnO:F, In₂O₃:Sn, In₂O₃:Mo, Cd₂SnO₄, ZnO:Al, TiO₂:Nb, Cd—Sn—O, or other metal oxides.

Optionally, the method further comprises forming a pattern comprising a gate electrode layer; and forming a pattern comprising a gate insulating layer; wherein the thin film transistor is a bottom gate thin film transistor, the gate electrode layer is disposed below the active layer, and the gate insulating layer is between the gate electrode layer and the active layer.

Optionally, the method further comprises forming a pattern comprising a gate electrode layer; and forming a pattern comprising a gate insulating layer; wherein the thin film transistor is a top gate thin film transistor, the gate insulating layer is disposed on top of the source electrode and the drain electrode, and the gate electrode is disposed on top of the gate insulating layer.

In another aspect, the present invention further provides an array substrate comprising the thin film transistor as described herein.

In another aspect, the present invention further provides a display device comprising the array substrate described herein.

### BRIEF DESCRIPTION OF THE FIGURES

The following drawings are merely examples for illustrative purposes according to various disclosed embodiments and are not intended to limit the scope of the present invention.

FIGS. 1A and 1B are diagrams illustrating the structure of a thin film transistor in embodiments.

FIG. 2 is a diagram illustrating the formation of a gate electrode in an embodiment.

FIG. 3 is a diagram illustrating the formation of a gate insulating layer, an active layer, and a conversion layer based on the embodiment as shown in FIG. 2.

FIG. 4 is a diagram illustrating the formation of a source layer and a drain electrode based on the embodiment as shown in FIG. 3.

FIG. 5 is a diagram illustrating the formation of a back channel based on the embodiment as shown in FIG. 4.

FIG. 6 is a diagram illustrating the structure of an array substrate in an embodiment.

FIG. 7 shows electronic properties of thin film transistors in some embodiments.

FIG. 8A is a microscopic view of a conventional TFT layers; and FIG. 8B is electronic properties of the conventional TFT.

FIG. 9A is a microscopic view of a TFT in one embodiment; and FIG. 9B is electronic properties of the TFT exemplified in FIG. 9A.

### DETAILED DESCRIPTION OF THE EMBODIMENTS

The disclosure will now describe more specifically with reference to the following embodiments. It is to be noted that the following descriptions of some embodiments are presented herein for purpose of illustration and description only. It is not intended to be exhaustive or to be limited to the precise form disclosed.

Manufacturing conventional metal oxide TFTs requires an additional patterning process to form an etching stop layer. Without the etching stop layer, when etching the source electrode and drain electrode in a conventional metal oxide TFT, the active layer will also be etched. This additional patterning process increases manufacturing costs and lowers production efficiency. This disclosure describes a high performance thin film transistor in which the active layer, even without the etching stop layer, is not etched, e.g., when etching the source electrode and drain electrode.

According to some embodiments, a conversion layer is formed on top of the active layer 4. The conversion layer 50 may be made of a conductive material which is resistant to the etching solution for etching source electrode and drain electrode, but can be converted into an insulating material. Various materials may be used for this purpose. Examples include, but are not limited to, n+ amorphous silicon. The n+ amorphous silicon material is highly resistant to the etching solution for the source electrode and the drain electrode. The conversion layer protects the active layer from being etched. Optionally the conversion layer can be first made from a material having amorphous silicon, followed by n+ doping the conversion layer to produce an n+ amorphous silicon conversion layer.

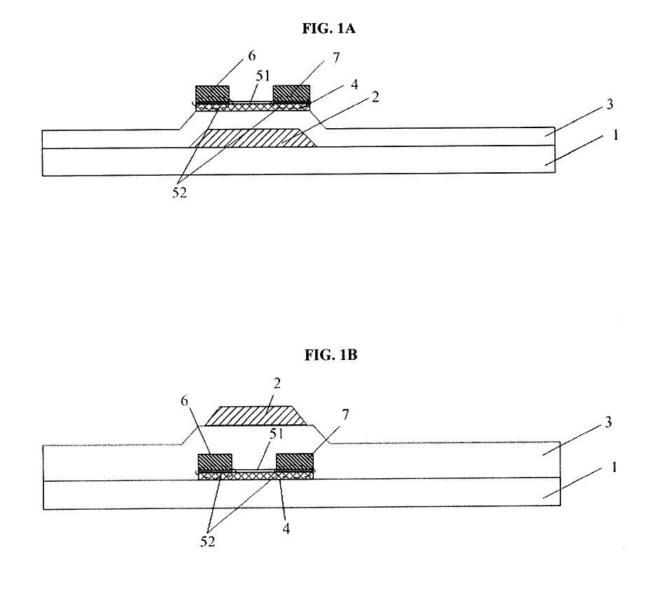

FIG. 1 is a diagram illustrating the structure of a thin film transistor in an embodiment. Referring to FIG. 1, the thin film transistor in the embodiment include a gate electrode 2, a source electrode 6, a drain electrode 7, an active layer 4, and a connecting layer 52 connecting the active layer 4 to the source electrode 6 or drain electrode 7. As shown in FIG. 1, the connecting layer 52 includes a first connecting layer connecting the active layer 4 to the source electrode 6, and a second connecting layer connecting the active layer 4 to the drain electrode 7. The thin film transistor further include an insulating layer 51 between the first connecting layer and the second connecting layer. The insulating layer 51 and the connecting layers 52 (including the first connecting layer and the second connecting layer) are integrally formed and disposed on top of the active layer 4. The connecting layers 52 are conductive, and the insulating layer 51 is insulating.

The term “conductive,” when referring to a layer, material, member, or structure is intended to mean such a layer, material, member, or structure through which a significant number of charge carriers (e.g., electrons, holes, or a combination thereof) may pass when operating an electronic device, including such layer, material, member, or structure, over a range of normal operating voltages (e.g., a designed voltage range for use by an end user of the electronic device). In some embodiments, a conductive material has a volume resistivity no greater than approximately 10⁺² ohm-cm. The term “insulating,” when referring to a layer, material, member, or structure, is intended to mean such layer, material, member, or structure is not conductive. In some embodiments, an insulating material has a volume resistivity no lower than 10⁺² ohm-cm.

The term “integrally formed” means that the body of the first connecting layer, the second connecting layer, and the insulating layer is a single unitary body. Typically, the integrally formed body may be made in a patterning method in which a same starting material for the first connecting layer, the second connecting layer, and the insulating layer is deposited and patterned in a single patterning process. One or more regions (the region corresponding to the insulating layer) within the integrally formed body may be treated or converted into a second material having different properties (e.g., from a conductive material to an insulating material).

Various conductive materials for the connecting layer 52 and various insulating materials for the insulating layer 51 may be used. Optionally, the first connecting layer and the second connecting layer are made of n+ amorphous silicon. Alternatively, they can be made of amorphous silicon following by n+ doping of the amorphous silicon. Optionally, the insulating layer comprises SiOₓ or SiNₓ. Optionally, the SiOₓ or SiNₓ material within the insulating layer can be made by treating the region corresponding to the insulating layer by an oxidation process or a nitrification process, and converting amorphous silicon or n+ amorphous silicon material within the region into SiOₓ or SiNₓ.

Various material for the active layer 4 may be used. Optionally, the active layer is made of a material including an oxide material, e.g., a metal oxide material. Optionally, the oxide material is selected from the group consisting of the following or combination thereof: HfInZnO (HIZO), amorphous InGaZnO (amorphous IGZO), InZnO, amorphous InZnO, ZnO:F, In₂O₃:Sn, In₂O₃:Mo, Cd₂SnO₄, ZnO:Al, TiO₂:Nb, and Cd—Sn—O.

The thin film transistor can be a top gate type or a bottom gate type. FIG. 1A shows a bottom gate thin film transistor in one embodiment. The bottom gate thin film transistor in the embodiment includes a gate electrode 2 disposed on top of a base substrate 1 and below the active layer 4, and a gate insulating layer 3 between the gate electrode 2 and the active layer 4. In the embodiment, the source electrode 6 and the drain electrode 7 are disposed on top of the active layer 4. The connecting layer 52 is disposed between the active layer 4 and the source/drain electrode 6/7, connecting the active layer 4 to the source electrode 6 and drain electrode 7, respectively. The insulating layer 51 is between the first connecting layer and the second connecting layer, and on top of the active layer 4. The connecting layer 52 and the insulating layer 51 are integrally formed as a same layer, and disposed on top of the active layer 4. FIG. 1B shows a top gate thin film transistor in one embodiment. The top gate thin film transistor in the embodiment includes a gate insulating layer 3 on top of the source electrode 6 and the drain electrode 7, and a gate electrode 2 on top of the gate insulating layer 3. In the embodiment, the active layer 4 is disposed on top of a base substrate 1, and the source electrode 6 and the drain electrode 7 are disposed on top of the active layer 4. The connecting layer 52 is disposed between the active layer 4 and the source/drain electrode 6/7, connecting the active layer 4 to the source electrode 6 and drain electrode 7, respectively. The insulating layer 51 is between the first connecting layer and the second connecting layer, and on top of the active layer 4. The connecting layer 52 and the insulating layer 51 are integrally formed as a same layer, and disposed on top of the active layer 4.

Accordingly, the thin film transistor in the embodiment does not require an etching stop layer to protect the active layer 4 from etching solutions used in etching the source electrode and the drain electrode. In some embodiments, such a thin film transistor may be manufactured, e.g., by a method including a step of forming a pattern comprising an active layer 4 and a conductive conversion layer 50 disposed on the active layer 4 in a single patterning process, and a step of treating a region of the conversion layer 50 and converting the conductive material within the region into an insulating material, thereby forming an insulating layer 51. In some embodiments, the conversion layer 50 and the active layer 4 have a same pattern (e.g., a same shape), and the conversion layer 50 is made of a conductive material. The method also includes a step of forming a pattern comprising a source electrode 6 layer and a step of forming a pattern comprising a drain electrode 7 layer.

In some embodiments, the conversion layer 50 includes a first region contacting the source electrode; a second region contacting the drain electrode; and a third region between the first region and the second region. Accordingly to some embodiments, the third region is treated and the conductive material within the third region is converted into an insulating material, thereby forming an insulating layer 51. The first and the second regions remain conductive (e.g., not treated), thereby forming connecting layers 52 (e.g., a first connecting layer and a second connecting layer). The treating step may be an oxidation process or a nitrification process. Optionally, the oxidation process may be performed using the one or more of the following processing parameters: a radio frequency ranging from 3 kW to 15 kW, a pressure ranging from 100 mT to 2000 mT, a gas flow ranging from 1000 to 15000 sccm, and a medium gas comprising Oz or N₂O. Optionally, the nitrification process may be performed using one or more of the following processing parameters: a radio frequency ranging from 3 kW to 15 kW, a pressure ranging from 100 mT to 2000 mT, a gas flow ranging from 1000 to 15000 sccm, and a medium gas comprising N₂, NH₃, or a mixture of N₂ and NH₃.

As discussed above, the conversion layer 50 may be made of a conductive material which is resistant to the etching solution for etching source electrode and drain electrode, but can be converted into an insulating material. For example, the n+ amorphous silicon material is highly resistant to the etching solution for the source electrode and the drain electrode, but can be converted into an insulating material by oxidation or nitrification. Optionally the conversion layer may be made of n+ amorphous silicon directly, or can be first made from a material having amorphous silicon, followed by n+ doping the conversion layer to produce an n+ amorphous silicon conversion layer. Optionally, the step of forming a pattern comprising the active layer and the conversion layer includes sequentially depositing a material for forming the active layer and a material containing n+ amorphous silicon for forming the conversion layer, and treating the third region and converting the n+ amorphous silicon within the third region into SiOₓ by the oxidation process or SiNₓ by the nitrification process.

Alternatively, the step of forming a pattern comprising the active layer and the conversion layer includes sequentially depositing a material for forming the active layer and a material containing amorphous silicon for forming the conversion layer, followed by n+ doping the amorphous silicon material, and treating the third region and converting the n+ amorphous silicon within the third region into SiOₓ by the oxidation process or SiNₓ by the nitrification process.

Optionally, prior to treating the third region of the conversion layer 50, the method further includes a step of annealing the conversion layer 50 and the active layer 4. Optionally, the annealing step is performed in a temperature ranging from 300° C. to 600° C. By annealing the conversion layer 50, the hydrogen content in a silicon-containing conversion layer 50 may be reduced. The annealing also helps improving the electronic properties of a metal oxide active layer 4. Examples of metal oxides suitable for making active layers 4 include, but are not limited to, HfInZnO (HIZO), amorphous InGaZnO (amorphous IGZO), InZnO, amorphous InZnO, ZnO:F, In₂O₃:Sn, In₂O₃:Mo, Cd₂SnO₄, ZnO:Al, TiO₂:Nb, Cd—Sn—O.

The method also includes a step of forming a pattern comprising a gate electrode 2 layer and a step of forming a pattern comprising a gate insulating layer 3. For top gate thin film transistor, the gate insulating layer 3 is disposed on top of the source electrode 6 and the drain electrode 7, and the gate electrode 2 is disposed on top of the gate insulating layer 3. For bottom gate thin film transistor, the gate electrode 2 layer is disposed below the active layer 4, and the gate insulating layer 3 is between the gate electrode 2 layer and the active layer 4.

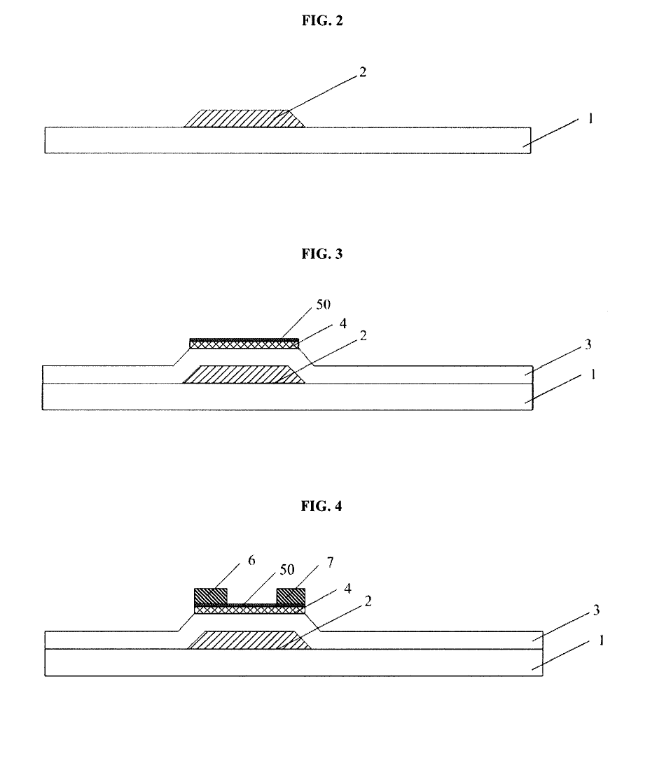

FIG. 2-FIG. 5 illustrate an exemplary method of manufacturing a bottom gate thin film transistor in an embodiment as shown in FIG. 1A. Specifically, the method in the embodiment includes a step of depositing gate electrode metal thin film on a base substrate by sputtering or thermal evaporation, forming a pattern comprising a gate electrode 2 layer (FIG. 2). Optionally, the metal thin film has a thickness ranging from 2000 to 10000 Å. The metal thin film can be made of a metal is selected from a group consisting of Cr, W, Cu, Ti, Ta, Mo, and combinations or alloys thereof. The metal thin film can be a single layer or can be a multi-layer structure comprising different metals in different layers.

Referring to FIG. 3, the method in the embodiment further includes a step of depositing a gate insulating layer 3 on the base substrate having a layer of gate electrode 2. The gate insulating layer 3 can be deposited, .e.g, by a Plasma Enhanced Chemical Vapor Deposition (PECVD) process. On top of the gate insulating layer 3, an active layer 4 material can be further deposited by sputtering or thermal evaporation. A conversion layer 50 material is then deposited on top of the active layer 4 material. A pattern comprising the active layer 4 and the conversion layer 50 can be formed by a patterning process, e.g., a single patterning process. Optionally, the conversion layer 50 and the active layer 4 have a same pattern (e.g., a same shape), and the conversion layer 50 is made of a conductive material, e.g., a silicon containing conductive material.

Optionally, the gate insulating layer 3 has a thickness ranging from 2000 to 8000 Å. Optionally, the gate insulating layer 3 is made of an oxide, a nitride, or an oxynitride. Optionally, for forming an oxide containing gate insulating layer 3, a reaction gas comprising SiH₄ and N₂O can be used as in the Plasma Enhanced Chemical Vapor Deposition (PECVD) process. Optionally, a reaction gas comprising SiH₄, NH₃, N₂, or a reaction gas comprising SiH₂Cl₂, NH₃, N₂, can be used for forming a nitride or oxynitride containing gate insulating layer 3.

Optionally, the active layer 4 has a thickness ranging from 100 to 2000 Å. Optionally, the active layer is made of an oxide semiconductor material. Examples of metal oxides suitable for making active layers 4 include, but are not limited to, HfInZnO (HIZO), amorphous InGaZnO (amorphous IGZO), InZnO, amorphous InZnO, ZnO:F, In₂O₃:Sn, In₂O₃:Mo, Cd₂SnO₄, ZnO:Al, TiO₂:Nb, Cd—Sn—O.

Optionally, the conversion layer has a thickness ranging from 100 to 2000 Å. Optionally, the conversion layer is made of a silicon-containing material, e.g., n+ amorphous silicon, or amorphous silicon followed by n+ doping.

Optionally, the conversion layer and/or the active layer is treated by an annealing process. Optionally, the annealing step is performed in a temperature ranging from 300° C. to 600° C. By annealing the conversion layer 50, the hydrogen content in a silicon-containing conversion layer 50 may be reduced. The annealing also helps improving the electronic properties of a metal oxide active layer 4.

Referring to FIG. 4, the method in the embodiment further includes a step of depositing a source-drain metal thin film by sputtering or thermal evaporation, and forming a pattern comprising source electrode 6 and drain electrode 7. The source-drain metal thin film is deposited on top of the conversion layer 50. Optionally, the source-drain metal thin film has a thickness ranging from 2000 to 10000 Å. Optionally, the source-drain metal thin film is made of a a metal is selected from a group consisting of Cr, W, Cu, Ti, Ta, Mo, and combinations or alloys thereof. The metal thin film can be a single layer or can be a multi-layer structure comprising different metals in different layers.

As shown in FIG. 4, the source electrode 6 and the drain electrode are disposed spaced apart and on top of the conversion layer 50. The conversion layer 50 includes a first region contacting the source electrode; a second region contacting the drain electrode; and a third region between the first region and the second region.

Examples of etching solutions for forming the source electrode 6 and the drain electrode 7 include phosphoric acid, nitric acid, and acetic acid. A conversion layer 50 comprising n+ amorphous silicon is resistant to these etching solution. The conversion layer 50 protects the active layer 4 from being etched.

Referring to FIG. 5, the method in the embodiment further include a step of treating the substrate using an oxidation process or a nitrification process, converting the material in the third region of the conversion layer 50 into an insulating material, thereby forming an insulating layer 51. The first and second regions of the conversion layer 50 are now covered by the source electrode 6 and the drain electrode 7, and remain conductive, thereby forming a connecting layer 52. The connecting layer 52 include a first connecting layer contacting the source electrode 6 and a second connecting layer contacting the drain electrode 7.

Referring to FIG. 5, the oxidation or nitrification process is indicated by arrows. An oxidation process converts the third region into an insulating layer 51 containing SiOₓ. An nitrification process converts the third region into an insulating layer 51 containing SiNₓ. Optionally, the oxidation process may be performed using the one or more of the following processing parameters: a radio frequency ranging from 3 kW to 15 kW, a pressure ranging from 100 mT to 2000 mT, a gas flow ranging from 1000 to 15000 sccm, and a medium gas comprising O₂ or N₂O. Optionally, the nitrification process may be performed using one or more of the following processing parameters: a radio frequency ranging from 3 kW to 15 kW, a pressure ranging from 100 mT to 2000 mT, a gas flow ranging from 1000 to 15000 sccm, and a medium gas comprising N₂, NH₃, or a mixture of N₂ and NH₃.

The first region and the second region of the conversion layer 50 are not treated by the oxidation process or the nitrification process, and remain conductive. For example, the first region and the second region are regions containing n+ amorphous silicon, which is in ohmic contact with the active layer 4, the source layer 6 and the drain layer 7. The third region is converted into an insulating material such as SiOₓ or SiNs, forming the back channel of the active layer 4.

FIG. 2-FIG. 5 exemplifies a method of manufacturing a bottom gate thin film transistor. The steps of forming the pattern comprising the active layer 4 and the conversion layer 50 can be similarly applied in making a top gate thin film transistor. In a bottom gate thin film transistor as shown in FIG. 1A, the gate electrode 2 is disposed on top of a base substrate 1 and below the active layer 4, and the gate insulating layer 3 is disposed between the gate electrode 2 and the active layer 4. In a top gate thin film transistor as shown in FIG. 1B, the gate insulating layer 3 is disposed on top of the source electrode 6 and the drain electrode 7, and the gate electrode 2 is disposed on top of the gate insulating layer 3.

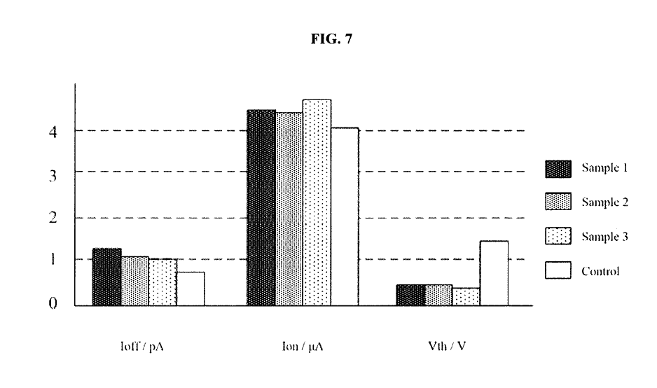

FIG. 7 shows electronic properties of thin film transistors in some embodiments. Referring to FIG. 7, electronic parameter measurement (EPM) were conducted on three samples and a control sample. The control sample is a conventional thin film transistor which is not treated by a plasma. The first sample is a thin film transistor treated by a nitrification process with the following processing parameters: a radio frequency of 4 kW, a gas flow of 14000 sccm, a pressure of 1500 mT, and a medium gas comprising N₂ for plasma treatment. The second sample is a thin film transistor treated by an oxidation process with the following processing parameters: a radio frequency of 10 kW, a gas flow of 2500 sccm, a pressure of 150 mT, and a medium gas comprising O₂ for plasma treatment. The third sample is a thin film transistor treated by an oxidation process with the following processing parameters: a radio frequency of 14 kW, a gas flow of 2500 sccm, a pressure of 200 mT, and a medium gas comprising O₂ for plasma treatment. Three electronic properties of these thin film transistors were measured, including turn-on current (Iₒₙ), turn-off voltage (I_{off}) and turn-on voltage (Vₜₕ). As shown in FIG. 7, the thin film transistor made by methods described herein possess electronic properties comparable to the conventional thin film transistor.

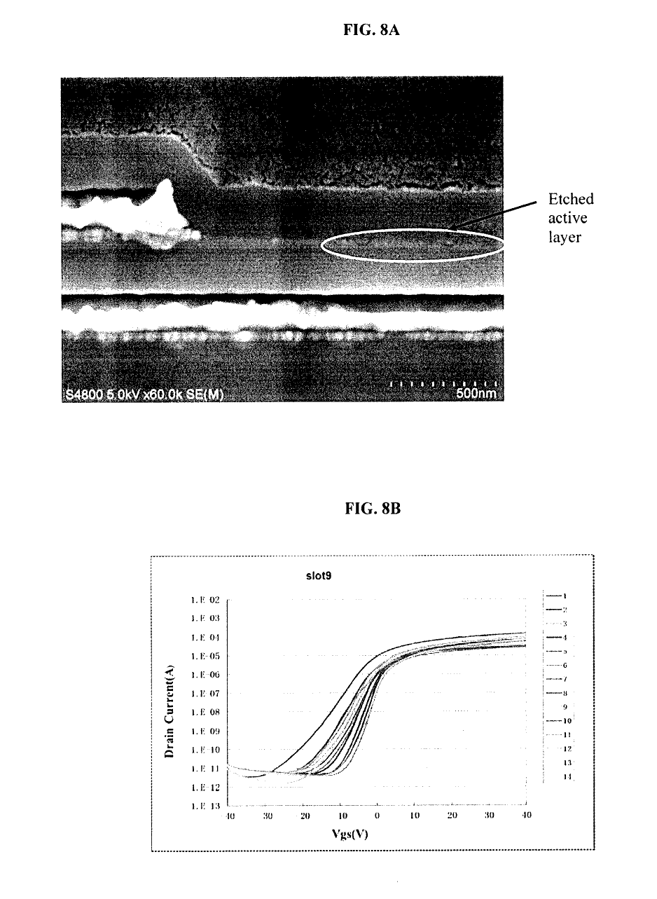

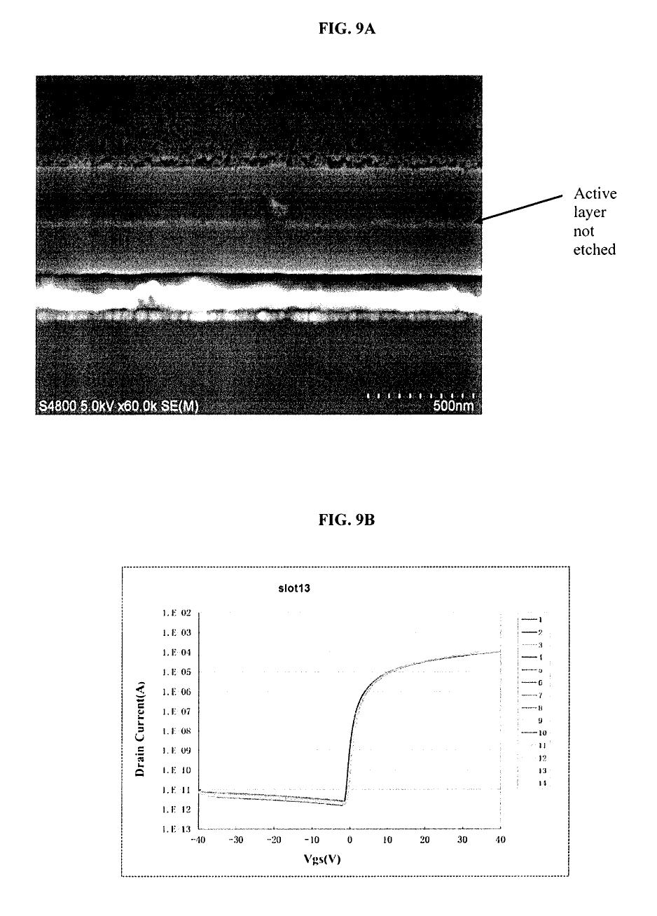

FIG. 8A shows a microscopic view of a conventional thin film transistor layers, FIG. 9A shows a microscopic view of an exemplary thin film transistor made by methods described herein. As shown in FIG. 9A, the active layer was not etched or damaged during the process of etching the source electrode and the drain electrode. The active layer in a conventional thin film transistor as shown in FIG. 8A, on the other hand, was damaged by the etching process. Superior electronic properties of the thin film transistor of FIG. 9A is shown in FIG. 9B. The thin film transistors of FIG. 8A have exceedingly high leakage current. For example, the leakage current for a thin film transistor of FIG. 8A can be as high as 1×10⁻⁷ A at V_{gs}=−10 V. The thin film transistors of FIG. 9A have a leakage current of very low magnitude, i.e., in the range of 1×10⁻¹² A at V_{gs}=−10 V. Also, the thin film transistors of FIG. 9A exhibit highly uniform transfer characteristics. As shown in FIG. 9B, the characteristics of each thin film transistor are nearly the same. The thin film transistors of FIG. 8A, however, show very large difference in magnitude as shown in FIG. 8B.

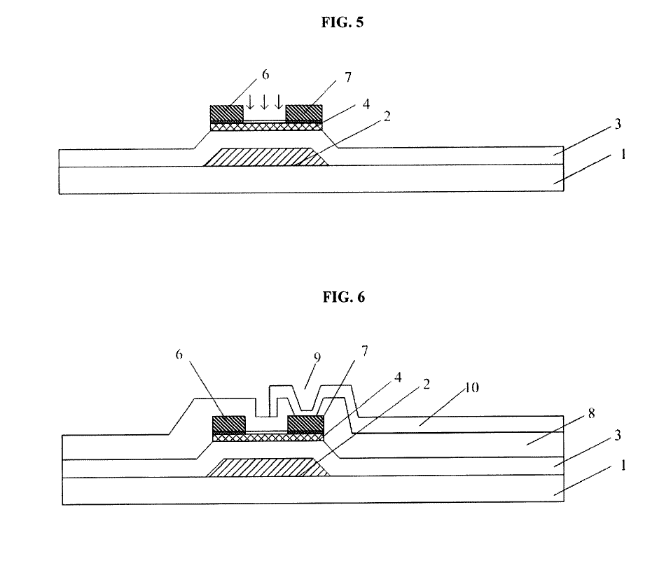

The present invention also provides an array substrate comprising the thin film transistor as described herein, or manufactured by a method described herein. FIG. 6 is a diagram illustrating the structure of an array substrate in an embodiment. The array substrate in the embodiment includes a top gate thin film transistor, e.g., of FIG. 1A, and can be manufactured using a method based on the method of manufacturing the thin film transistor described above. After treating the third region of the conversion layer and converting the conductive material within the third region into an insulating material, a passivation layer 8 can be deposited on top of the source electrode 6 and the drain electrode 7. The passivation layer 8 can be patterned by a patterning process, and a contact via 9 can be formed in the passivation layer 8 connecting the drain electrode 7 and a pixel electrode.

Optionally, the passivation layer 8 has a thickness ranging from 500 to 3000 Å. The passivation layer 8 can have a single layer structure comprising silicon oxide, a double-layer structure comprising silicon oxide and silicon nitride, or a triple-layer structure comprising silicon oxide, silicon oxynitride and silicon nitride. The reason gases for making silicon oxide include, but are not limited to, N₂O. SiH₄. The reason gases for making silicon oxynitride include, but are not limited to, N₂O, SiH₄, NH₃, N₂. The reason gases for making silicon nitride include, but are not limited to, SiH₄, NH₃, N₂, or SiH₂Cl₂, NH₃, N₂.

After forming the passivation layer 8, the method in the embodiment further comprises depositing a transparent conductive layer by sputtering or thermal evaporation, and forming a pattern comprising a transparent pixel electrode layer 10. Optionally, the transparent conductive layer has a thickness ranging from 100 to 2000 Å. The transparent conductive material can be, for example, ITO or IZO, or other transparent metal oxide.

The present invention further provides a display device having the array substrate described herein. The display device can be of any type, e.g., a liquid crystal display device, a liquid crystal television, an AMOLED display device, an AMOLED television, a laptop, a computer, a mobile phone, PDA, OPS, an electronic paper display device, an in-vehicle display device, a projection display, a camera, a video recorder, a digital camera, an electronic watch, a calculator, a meter, a public display, a virtual display, and so on.

The foregoing description of some embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred.

The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A thin film transistor comprising:
a source electrode;
a drain electrode;
an active layer;
a first connecting layer connecting the active layer to the source electrode;
a second connecting layer connecting the active layer to the drain electrode; and
an insulating layer between the first connecting layer and the second connecting layer;
wherein the insulating layer, the first connecting layer, and the second connecting layer are integrally formed and disposed on the active layer, the first connecting layer and the second connecting layer are conductive.

2. The thin film transistor of claim 1, wherein the first connecting layer and the second connecting layer comprise n+ amorphous silicon, and the insulating layer comprises SiOₓ or SiNₓ.

3. The thin film transistor of claim 1, wherein the active layer comprises an oxide material.

4. The thin film transistor of claim 3, wherein the oxide material is selected from the group consisting of the following or combination of: HfInZnO (HIZO), amorphous InGaZnO (amorphous IGZO), InZnO, amorphous InZnO, ZnO:F, In₂O₃:Sn, In₂O₃:Mo, Cd₂SnO₄, ZnO:Al, TiO₂:Nb, and Cd—Sn—O.

5. The thin film transistor of claim 1, wherein the thin film transistor is a bottom gate thin film transistor further comprising:
a gate electrode disposed below the active layer; and
a gate insulating layer between the gate electrode and the active layer.

6. The thin film transistor of claim 1, wherein the thin film transistor is a top gate thin film transistor further comprising:
a gate insulating layer disposed on top of the source electrode and the drain electrode; and
a gate electrode on top of the gate insulating layer.

7. A method of manufacturing a thin film transistor, comprising:
forming a pattern comprising an active layer and a conversion layer disposed on the active layer in a single patterning process, wherein the conversion layer and the active layer have a same pattern, and the conversion layer is made of a conductive material; and
treating a region of the conversion layer and converting the conductive material within the region into an insulating material, thereby forming an insulating layer.

8. The method of claim 7, wherein the treating is performed by an oxidation process or a nitrification process.

9. The method of claim 7, further comprising:
forming a pattern comprising a source electrode layer; and
forming a pattern comprising a drain electrode layer.

10. The method of claim 9, wherein the conversion layer comprises a first region contacting the source electrode; a second region contacting the drain electrode; and a third region between the first region and the second region; the method comprising:
treating the third region and converting the conductive material within the third region into the insulating material, thereby forming the insulating layer;
wherein the first region and the second region remain conductive, thereby forming a first connecting layer connecting the active layer to the source electrode and a second connecting layer connecting the active layer to the drain electrode.

11. The method of claim 10, wherein the step of forming the pattern comprising the active layer and the conversion layer comprising:
sequentially depositing a first material for forming the active layer and a second material for forming the conversion layer; wherein the second material comprises n+ amorphous silicon; and
treating the third region and converting the n+ amorphous silicon within the third region into SiOₓ by the oxidation process or SiNₓ by the nitrification process.

12. The method of claim 10, wherein the step of forming the pattern comprising the active layer and the conversion layer comprising:
sequentially depositing a first material for forming the active layer and a second material for forming the conversion layer; wherein the second material comprises amorphous silicon;
n+ doping the second material; and
treating the third region and converting the n+ amorphous silicon within the third region into SiOₓ by the oxidation process or SiNₓ by the nitrification process.

13. The method of claim 11, wherein the oxidation process comprising the following processing parameters: a radio frequency ranging from 3 kW to 15 kW, a pressure ranging from 100 mT to 2000 mT, a gas flow ranging from 1000 sccm to 15000 sccm, and a medium gas comprising O₂ or N₂O.

14. The method of claim 11,
wherein the nitrification process comprising the following processing parameters: a radio frequency ranging from 3 kW to 15 kW, a pressure ranging from 100 mT to 2000 mT, a gas flow ranging from 1000 to 15000 sccm, and a medium gas comprising N₂, NH₃, or a mixture of N₂ and NH₃.

15. The method of claim 10, further comprising, prior to the step of treating the third region, annealing the conversion layer in a temperature ranging from 300° C. to 600° C.

16. The method of claim 7, wherein the active layer comprises an oxide material.

17. The method of claim 16, wherein the oxide material is selected from the group consisting of the following or combination thereof: HfInZnO (HIZO), amorphous InGaZnO (amorphous IGZO), InZnO, amorphous InZnO, ZnO:F, In₂O₃:Sn, In₂O₃:Mo, Cd₂SnO₄, ZnO:Al, TiO₂:Nb, Cd—Sn—O, or other metal oxides.

18. The method of claim 7, further comprising:
forming a pattern comprising a gate electrode layer; and
forming a pattern comprising a gate insulating layer;
wherein the thin film transistor is a bottom gate thin film transistor, the gate electrode layer is disposed below the active layer, and the gate insulating layer is between the gate electrode layer and the active layer.

19. (canceled)

20. An array substrate comprising the thin film transistor of claim 1.

21. A display device comprising the array substrate of claim 20.
